(19) United States
(12) Patent Application Publication
(10) Pub. No.: US 2026/0333929 A1
(43) Pub. Date: Oct. 22, 2026

(54) OPTOELECTRONIC DEVICE AND SYSTEM FOR OPTICAL DATA COMMUNICATION

(71) Applicant: ams-OSRAM International GmbH, Regensburg (DE)

(72) Inventors: Adrian Avramescu, Regensburg (DE); Michael Binder, Barbing (DE); Norwin von Malm, Nittendorf (DE)

(21) Appl. No.: 19/485,210

(22) PCT Filed: May 22, 2024
(86) PCT No.: PCT/EP2024/064148

§ 371 Date: Nov. 17, 2025

(30) Foreign Application Priority Data
May 23, 2023 (DE) 10 2023 113 465.5

(51) Int. Cl. H10F 55/00; H10F 55/255

(52) U.S. Cl. CPC H10F 55/18; H10F 55/255

(57) ABSTRACT

In an embodiment an optoelectronic device includes a carrier substrate and a semiconductor layer stack arranged on the carrier substrate, wherein the semiconductor layer stack includes a first layer, a second layer, a third layer, a first active region between the first and second layers and a second active region between the second and third layers, wherein the first and second layers include a doping of a first conductivity type with the second layer having a higher doping concentration than the first layer, wherein the third layer includes a doping of a second conductivity type different from the first conductivity type, and wherein the first active region includes a smaller bandgap than the second active region.

### CROSS-REFERENCE TO RELATED APPLICATIONS

This patent application is a national phase filing under section 371 of PCT/EP2024/064148, filed May 22, 2024, which claims the priority of German patent application no. 10 2023 113 465.5, filed May 23, 2023, each of which is incorporated herein by reference in its entirety.

### TECHNICAL FIELD

The present invention concerns an optoelectronic device, an arrangement of optoelectronic devices and a system for optical data communication. The present invention further concerns a method for operating an optoelectronic device and for operating a system for optical data communication.

### BACKGROUND

Today's Internet relies on large data centres. However, their high-power consumption poses problems to ensure their operation with purely sustainable energy sources. Most of the power is consumed not for computations, but for data transmission over short distances (<<10 m): CPU to GPU, server to server, rack to rack.

Currently, short-range data communication is either done electrically, mainly by copper (Cu) or aluminium (Al) feed lines and wires (intra-chip or within mainboard), or optically by the combination of near infrared (NIR) vertical-cavity surface-emitting lasers (VCSEL) with optical fibres. The metals however cause electrical power losses due to their specific resistance and the VCSELs on the other hand need a certain threshold current (Iₜₕ) to start laser emission, typically in the mA regime. Together with the necessary forward voltage this threshold current Iₜₕ defines a dissipated (electrical) power of some mW.

To reduce the power for optical short range data transmission there are activities on using μ-LEDs to tackle the challenge of high power consumption. μ-LEDs namely have the advantage of a possible operation with low currents (1-500 μA per pixel), which is many factors lower as for lasers, e.g. VCSELs, and they don't need a (lasing-)threshold, which needs to be passed. In addition, μ-LEDs have a small footprint (<5 μm possible) and can be transferred to backplane wafers by common display technologies, thus a high parallelization while transferring the μ-LEDs can be achieved further reducing the power consumption while manufacturing the hardware.

The use of small optoelectronic components such as μ-LEDs for optical data communication has thus major benefits to, e.g., VCSEL technology due to better scalability and lower current operation, saving energy in particular for data transmission over short and midrange distances.

The use of small optoelectronic components such as μ-LEDs however requires, besides a high quantum efficiency, a very fast “switchability” of the emitters in order to allow for high data rates. One limitation with respect to this is radiative recombination lifetime, limiting the rise and fall time of light emission when modulating or turning on/off the μ-LED. This effect in particular plays a great role when using μ-LEDs due to their large surface to volume ratio.

Currently known approaches to decrease radiative recombination lifetime include for example background doping (e.g. in the QW barriers) in order to increase charge carrier density for certain charge carrier types, the use of Quantum dots, and/or to try and achieve a high current density.

These methods can however only improve the performance of the optoelectronic components to a certain extent.

### SUMMARY

Embodiments provide an optoelectronic component as well as a system for optical data communication that counteracts at least some of the disadvantages mentioned.

Embodiments provide an optoelectronic component as well as a system using such optoelectronic components by means of which via a single optical fibre data for optical data communication can be sent back and forth within the single optical fibre. This can be done by using monolithically integrated μ-LEDs and μ-Detectors as optoelectronic components. Depending on the operation mode the optoelectronic devices can be used either as emitters or as detectors allowing a “universal” use of the same. By this the footprint of such a system can be reduced.

Embodiments provide a semiconductor layer stack with a respective order of different layers which when biased in forward direction is configured to emit light of a desired wavelength and when biased with 0V or in reverse direction is configured to detect light of a desired wavelength. The semiconductor layer stack comprises a first layer of a first conductivity type, a second layer of the same conductivity type and a third layer of a second conductivity type different to the first conductivity type. The semiconductor layer stack further comprises a first active region between the first and the second layer and a second active region between the second and the third layer with the first active region comprising a smaller bandgap than the second active region. The second layer thereby acts as spacer layer with a higher doping concentration of the first conductivity type than the first layer.

A biasing of the semiconductor layer stack in forward direction causes the space charge region to close such that holes recombine with electrons only in the second active region emitting light with the energy of the band gap of the second active region. A biasing of the semiconductor layer stack with 0V on the other hand causes the space charge region to remain such that it covers the second active region. Light with energy greater than the bandgap of the second active region (inclusively) can then be detected within the second active region. A biasing of the semiconductor layer stack in reverse direction lastly causes the space charge region to enlarge such that it covers in addition to the second active region the first active region. Light with energy greater than the bandgap of the first active region (inclusively) can then be detected over the whole enlarged space charge region.

In a first embodiment an optoelectronic device, in particular combined μ-LED and μ-Detector, is provided. The optoelectronic device comprises a carrier substrate and a semiconductor layer stack arranged on the carrier substrate. The semiconductor layer stack comprises a first layer, a second layer, a third layer, a first active region between the first and the second layer and a second active region between the second and the third layer. The first and the second layer comprise a doping of a first conductivity type with the second layer having a higher doping concentration than the first layer and the third layer comprises a doping of a second conductivity type different to the first conductivity type. For example, the first and second layer can comprise an n-doping and the third layer can comprise a p-doping, but the ordering can also be the other way around. In addition, the first active region comprises a smaller bandgap than the second active region. The active regions can for example each comprise a quantum well or multi quantum well structure.

In some embodiments, the optoelectronic device is configured to emit light when applying a voltage in forward direction between the first layer and the third layer/to the semiconductor layer stack and the optoelectronic device is configured to detect light, when applying a voltage of 0V or in reverse direction between the first layer and the third layer/to the semiconductor layer stack. In case of the first and the second layer comprising an n-doping and the third layer comprising a p-doping, a voltage in forward direction can mean that a voltage greater than 0V is applied between the first layer and the third layer and a voltage in reverse direction can mean that a voltage smaller than 0V is applied between the first layer and the third layer. This results in the semiconductor layer stack being biased in forward or reverse direction respectively.

In some embodiments, the optoelectronic device is a combined μ-LED and μ-Detector. A such a combined μ-LED and μ-Detector can in particular be a device with edge lengths smaller than 100 μm, smaller than 50 μm, smaller than 20 μm, smaller than 10 μm or smaller than 5 μm being configured to emit and detect light of a desired wavelength.

In some embodiments, the optoelectronic device further comprises a top contact element in electric contact with the third layer and a bottom contact element in electric contact with the first layer.

At least one of the top or the bottom contact element can for example be substantially transparent for light with energy less than or equal to the bandgap of the second active region.

In particular the top or the bottom contact element can form a light emitting and/or light incident area of the optoelectronic device through which light generated in the second active region is outcoupled from the optoelectronic device and/or through which light is incoupled into the optoelectronic device to be detected. Such a substantially transparent contact element can for example be formed of a transparent conductive oxide (TCO) such as for example Indium Tin Oxide (ITO). The light emitting area/light incident area can be formed by either the top contact element or the bottom contact element itself or further structure(s)/element(s) as described later herein.

In some embodiments, the other one of the top and bottom contact element not being substantially transparent comprises a reflective material layer covering the underlying layer of the first and third layer. In case of the top contact element the reflective material layer can cover the third layer opposite the second active region or in case of the bottom contact element the reflective material layer can cover the first layer opposite the first active region. This allows a directional radiation of generated light in the direction of the light emitting area and a more efficient outcoupling of the generated light through the light emitting area. On the other hand, the detection efficiency of the optoelectronic device can be increased, as not yet detected but through the semiconductor layer stack propagated light is reflected within the optoelectronic device to be possibly detected “at a further attempt” when propagating back again through the semiconductor layer stack.

In some embodiments, the top contact element comprises a first portion and a second portion arranged on the third layer opposite the second active region distant from each other. In some embodiments, the bottom contact element comprises a first portion and a second portion arranged on the first layer opposite the first active region distant from each other. The separate portions of the top and/or bottom contact element can for example form separate electric contacts for controlling an emitter and a detector portion of the optoelectronic device separately.

In some embodiments, the semiconductor layer stack comprises an emitter portion and a detector portion, wherein the emitter portion comprises at least a portion of the second active region and the third layer and wherein the detector portion comprises at least a portion of the first layer and the first active region. In the detector portion for example the second active region and the third layer and optionally the second layer can be removed. In the emitter portion on the other hand the first layer and the first active region and optionally the second layer can for example be removed. The emitter portion and the detector portion can for example be spaced from each other by a gap.

In some embodiments, the second active region and the third layer and optionally the second layer can for example be partially removed such that the semiconductor layer stack forms a step with the first layer and the first active region and optionally the second layer forming a base on which a stump of the second active region and the third layer and optionally the second layer is arranged. The portion of the semiconductor layer stack comprising the stump can thereby form the emitter portion whereas at least the area of the semiconductor layer stack surrounding/adjacent to the stump and in particular the whole base of the semiconductor layer stack can form the detector portion.

In some embodiments, the first active region and the first layer and optionally the second layer can for example be partially removed such that the semiconductor layer stack forms a step with the third layer and the second active region and optionally the second layer forming a base on which a stump of the first active region and the first layer and optionally the second layer is arranged. The portion of the semiconductor layer stack comprising the stump can thereby form the detector portion whereas at least the area of the semiconductor layer stack surrounding/adjacent to the stump and in particular the whole base of the semiconductor layer stack can form the emitter portion.

In both aforementioned cases, the emitter portion and the detector portion can for example be spaced from each other by a gap. However, emitter portion and the detector portion can for example also be connected via their common base.

The semiconductor layer stack can be of any shape, for example a truncated pyramidal shape with angled side surfaces or a truncated cylindrical shape with angled side surfaces. Such angled side surfaces can for example result from a mesa etching process. The semiconductor layer stack can however also comprise (a) step(s) with a base of the semiconductor layer stack having a larger cross section as for example (a) stump(s) of the semiconductor layer stack arranged on the base. The stump(s) in such a case can for example be arranged centred of the base or at/along one of the side surfaces of the base. Base and/or stump can each for example be again of any shape, for example a truncated pyramidal shape with angled side surfaces or a truncated cylindrical shape with angled side surfaces. These exemplary embodiments are however not to be understood in a limiting way but just as possible embodiments. Any other arrangements, shapes and cross sections are also possible.

In some embodiments, the semiconductor layer stack comprises a plurality of emitter portions and a detector portion, wherein the emitter portions comprises at least a portion of the second active region and the third layer. In the emitter portions the first layer and the first active region and optionally the second layer can for example be removed such that the semiconductor layer stack forms steps with the first layer and the first active region and optionally the second layer forming a base on which stumps of the second active region and the third layer and optionally the second layer are arranged. The portions of the semiconductor layer stack comprising a stump can thereby form the emitter portions whereas at least the area of the semiconductor layer stack surrounding/adjacent to the stumps and in particular the whole base of the semiconductor layer stack can form the detector portion. The emitter portions and the detector portion can for example be spaced from each other by a gap. By this, a redundancy between the emitters can be achieved in case of one or several emitter portions fail.

In some embodiments, the optoelectronic device further comprises a middle contact element being in electric contact with the second layer and/or the first active region or the second active region. In particular in case of the semiconductor layer stack being partially removed to form the emitter portion and the detector portion, the middle contact element can form a further contact element to be arranged on the recessed layer/active region. In case of the middle contact element being directly arranged on the first active region or the second active region, the middle contact element can be a Schottky contact element being in electric contact with the respective active region. Hence the emitter and detector portion can be operated separately by applying a voltage between the top and the bottom contact element and by applying a voltage between the middle contact element and the first or third contact element respectively.

Hence in some embodiments, the optoelectronic device is configured to emit light when applying a voltage in forward direction between the top contact element and the bottom contact element and the optoelectronic device is configured to detect light, when applying a voltage of 0V or in reverse direction between the bottom element and the middle contact element. And in some other embodiments, the optoelectronic device is configured to emit light when applying a voltage in forward direction between the top contact element and the middle contact element and the optoelectronic device is configured to detect light, when applying a voltage of 0V or in reverse direction between the bottom element and the top contact element.

In some embodiments, the optoelectronic device comprises a reflective coating extending alongside surfaces of the semiconductor layer stack. This for example allows a directional radiation of light generated in the semiconductor layer stack in the direction of the light emitting area and a more efficient outcoupling of the generated light through the light emitting area. On the other hand, the detection efficiency of the optoelectronic device can be increased, as not yet detected but through the semiconductor layer stack propagated light is reflected within the semiconductor layer stack to be possibly detected “at a further attempt” when propagating back again through the semiconductor layer stack.

In some embodiments, a dielectric material or layer is arranged between the side surfaces of the semiconductor layer stack and the reflective coating. In this way, a short circuit within the optoelectronic device that could be caused by the reflective coating when it electrically connects the first, optional middle, and top contact element can be prevented.

In some embodiments, the optoelectronic device further comprises an outcoupling structure on the top contact element opposite the carrier substrate or on the bottom contact element opposite the carrier substrate and/or on the middle contact element opposite carrier substrate. The outcoupling/incoupling structure for example forms the light emitting area/light incident area. The outcoupling/incoupling structure can for example be a surface roughening of the top/bottom/middle contact element or of a further layer arranged on the top/bottom/middle contact element. In this way an out- and/or incoupling of light from and into the optoelectronic device can be improved, as well as a directionality of the outcoupled light can be improved. In addition, an incoupling of light into an adjacent optical fibre can by this be improved.

In some embodiments, the optoelectronic device further comprises an optical element on the top contact element opposite the carrier substrate or on the bottom contact element opposite the carrier substrate and/or on the middle contact element opposite carrier substrate. The optical element can for example be a μ-lens or a photonic structure. In this way an out- and/or incoupling of light from and into the optoelectronic device can be improved, as well as a directionality of the outcoupled light can be improved. In addition, an incoupling of light into an adjacent optical fibre can by this be improved.

In some embodiments, the carrier substrate comprises a supply circuit being in electric contact with the top and/or bottom and/or middle contact element. The carrier substrate can for example be in form of a CMOS element or a portion of a CMOS wafer.

In some embodiments, the carrier substrate is bonded to extensions of the bottom, middle and top contact element, or directly bonded to at least the bottom contact element and in particular bonded to the middle and top contact element. The carrier substrate can however also be monolithically integrated with the semiconductor layer stack and the contact elements. It is also conceivable that the optoelectronic device comprises no carrier substrate and is at a later stage placed on a respective carrier substrate.

In some embodiments, optoelectronic device(s) according to the proposed principle can be processed as individual elements, capable of being for example transfer printed or transferred onto a carrier substrate. In some embodiments, optoelectronic devices according to the proposed principle can however also be processed as an array/a plurality of optoelectronic devices arranged adjacent on a carrier substrate forming an arrangement.

In a further embodiment it is thus provided an arrangement comprising a carrier substrate and a plurality of optoelectronic devices according to some embodiments of the proposed principle arranged adjacent to each other on a common carrier substrate. In some embodiments, the optoelectronic devices are thereby arranged in an array in rows and columns and for example connected with a filler material, for example a polymer filler material. By the filler material, the optoelectronic devices can for example be optically isolated from each other.

Monolithic integration of emitters and detectors such as described above allows fabrication of a compact and well-aligned arrangement of optoelectronic devices. Furthermore, very short connections to a carrier substrate such as a CMOS driver by using vias for vertical stacking can be achieved.

In a further embodiment it is provided a system for optical data communication comprising a first arrangement of optoelectronic devices and a second arrangement of optoelectronic devices. The optoelectronic devices of the first arrangement are thereby optically coupled with a respective optoelectronic device of the second arrangement to transmit optical data. Each optoelectronic device of the first and second arrangement thereby comprises an emitter and a detector portion such that via one single optical data can be transmitted back and forth between the two arrangements. At least one of the first and second arrangement is thereby an arrangement according to some of aforementioned embodiments.

In some embodiments, the optoelectronic devices of the first arrangement are configured to emit light of a first wavelength and the optoelectronic devices of the second arrangement are configured to detect the light of the first wavelength emitted by the respective optoelectronic device of the first arrangement. Thus, the first arrangement is configured to send optical data and the second arrangement is configured to detect optical data. In addition, the optoelectronic devices of the second arrangement are configured to emit light of a second wavelength and the optoelectronic devices of the first arrangement are configured to detect the light of the second wavelength emitted by the respective optoelectronic device of the second arrangement. Thus, the second arrangement is also configured to send optical data and the first arrangement is configured to also detect optical data. For optical data communication it is thus only one arrangement configured to emit and detect optical data necessary on each side of the communicating objects and a communication between the communicating objects is realized by sending and emitting data at different points of time or in case of the first and second wavelength being different by sending and detecting data with different wavelengths at the same time. The optoelectronic devices of the first arrangement are therefore for example be configured to emit at a first point of time light of a first wavelength and the optoelectronic devices of the second arrangement are configured to detect the light of the first wavelength emitted by the respective optoelectronic device of the first arrangement at the first point of time. In addition the optoelectronic devices of the second arrangement are configured to emit at a second point of time light of the second wavelength and the optoelectronic devices of the first arrangement are configured to detect the light of the second wavelength emitted by the respective optoelectronic device of the second arrangement at the second point of time.

In some embodiments, the first and second wavelength are substantially the same, and thus the first and second arrangement comprise substantially the same optoelectronic devices. In some embodiments, the first and second wavelength are however different from each other. In latter case, above each detector portion of the optoelectronic devices of the first arrangement a first wavelength filter can be arranged and above each detector portion of the optoelectronic devices of the second arrangement a second wavelength filter can be arranged. The first wavelength filter can thereby be configured to transmit light of the second wavelength but block light of the first wavelength and the second wavelength filter can thereby be configured to transmit light of the first wavelength but block light of the second wavelength.

In a further embodiment it is provided a method for operating an optoelectronic device according to some embodiments of the proposed principle. The method comprises the steps:
applying a voltage in forward direction between the third layer and the first or second layer to emit light of a first wavelength;
outcoupling the light of the first wavelength of the optoelectronic device through a light emitting area arranged on a side of the semiconductor layer stack opposite the carrier substrate; and
applying a voltage equal to 0V or in reverse direction between the first layer and the third or second layer to detect light of a second wavelength incident on a light incident area of the optoelectronic device arranged on a side of the semiconductor layer stack opposite the carrier substrate.

In some embodiments, the first and second wavelength are substantially the same, in some embodiments, the first and second wavelength are however different from each other.

In a further embodiment it is provided a method for operating a system according to some embodiments of the proposed principle. The method comprises the steps:
emitting light of a first wavelength by means of a first optoelectronic device of the first arrangement;
coupling the light of the first wavelength into a first optical fibre;
transmitting the light of the first wavelength to a respective first optoelectronic device of the second arrangement;
coupling the light of the first wavelength into the first optoelectronic device of the second arrangement; and
detecting the light of the first wavelength by means of the first optoelectronic device of the second arrangement.

In some embodiments, the method further comprises the steps:
emitting light of a second wavelength by means of the first optoelectronic device of the second arrangement;
coupling the light of the second wavelength into the first optical fibre;
transmitting the light of the second wavelength to the first optoelectronic device of the first arrangement;
coupling the light of the second wavelength into the first optoelectronic device of the first arrangement; and
detecting the light of the second wavelength by means of the first optoelectronic device of the first arrangement.

### BRIEF DESCRIPTION OF THE DRAWINGS

Further embodiments and embodiments in accordance with the proposed principle will become apparent in relation to the various embodiments and examples described in detail in connection with the accompanying drawings in which:

FIG. 1 shows an embodiment of an optoelectronic device in accordance with some embodiments of the proposed principle;

FIG. 2 illustrates the space charge region of an optoelectronic device in accordance with some embodiments of the proposed principle in dependence on a voltage applied to it;

FIG. 3 shows another embodiment of an optoelectronic device in accordance with some embodiments of the proposed principle;

FIG. 4 illustrates yet another embodiment of an optoelectronic device in accordance with some embodiments of the proposed principle;

FIG. 5 shows yet another embodiment of an optoelectronic device in accordance with some embodiments of the proposed principle;

FIGS. 6A and 6B illustrate a cross sectional view and a top view of yet another embodiment of an optoelectronic device in accordance with some embodiments of the proposed principle;

FIG. 7 shows a top view of yet another embodiment of an optoelectronic device in accordance with some embodiments of the proposed principle;

FIG. 8 illustrates an embodiment an arrangement with a plurality of optoelectronic devices in accordance with some embodiments of the proposed principle;

FIGS. 9A and 9B show steps of a method for operating an optoelectronic device in accordance with some embodiments of the proposed principle;

FIG. 10 illustrates an embodiment of a system for optical data communication in accordance with some embodiments of the proposed principle; and

FIG. 11 shows another embodiment of a system for optical data communication in accordance with some embodiments of the proposed principle.

### DETAILED DESCRIPTION OF ILLUSTRATIVE EMBODIMENTS

The following embodiments and examples disclose various combinations according to the proposed principle. The embodiments and examples are not always to scale. Likewise, different elements can be displayed enlarged or reduced in size to emphasize individual embodiments. It goes without saying that the individual embodiments of the embodiments and examples shown in the figures can be combined with each other without further ado, without this contradicting the principle according to the invention. Some embodiments show a regular structure or form. It should be noted that in practice slight differences and deviations from the ideal form may occur without, however, contradicting the inventive idea.

In addition, the individual figures and embodiments are not necessarily shown in the correct size, nor do the proportions between individual elements have to be essentially correct. Some embodiments are highlighted by showing them enlarged. However, terms such as “above”, “over”, “below”, “under” “larger”, “smaller” and the like are correctly represented with regard to the elements in the figures. So it is possible to deduce such relations between the elements based on the figures.

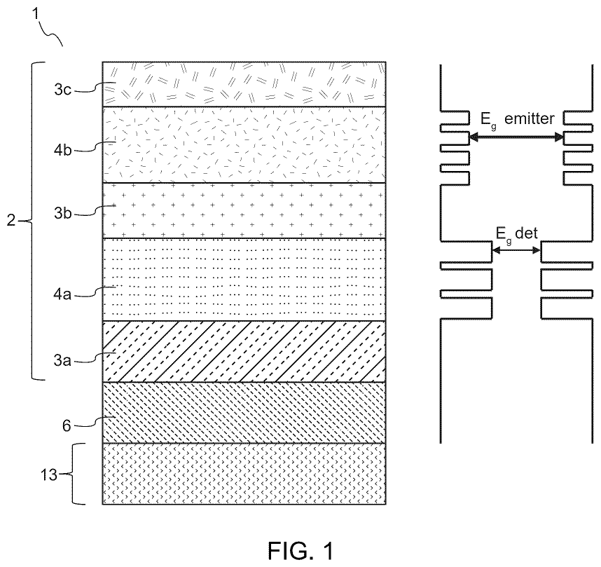

FIG. 1 shows a first embodiment of an optoelectronic device 1 in accordance with some embodiments of the proposed principle. The optoelectronic device 1 comprises a semiconductor layer stack 2 arranged on a carrier substrate 13. The semiconductor layer stack 2 comprises a first layer 3a, a second layer 3b and a third layer 3c. The semiconductor layer stack 2 further comprises a first active region 4a between the first and the second layer 3a, 3b and a second active region 4b between the second and the third layer 3b, 3c. The first and the second layer 3a, 3b comprise a doping of the same conductivity type with the second layer having a higher doping concentration and the third layer comprises a doing concentration of a different conductivity type. For example, the first layer and the second layer is an n-doped layer whereas the second layer is a p-doped layer or the other way around.

In the embodiment shown, the optoelectronic device 1 further comprises a bottom contact element 6 electrically contacting the first layer 3a and a not shown top contact element 8 electrically contacting the third layer 3c.

As shown in the right of FIG. 1, the first active region 4a comprises a smaller bandgap than the second active region 4b or at least substantially equal bandgap. Thus, the energy E_{g}^{det} of the first active region 4a is smaller or at least substantially equal to the energy E_{g}^{emitter} of the second active region 4b. In addition, as shown in the right of FIG. 1, the active regions 4a, 4b each comprise a multi quantum well structure.

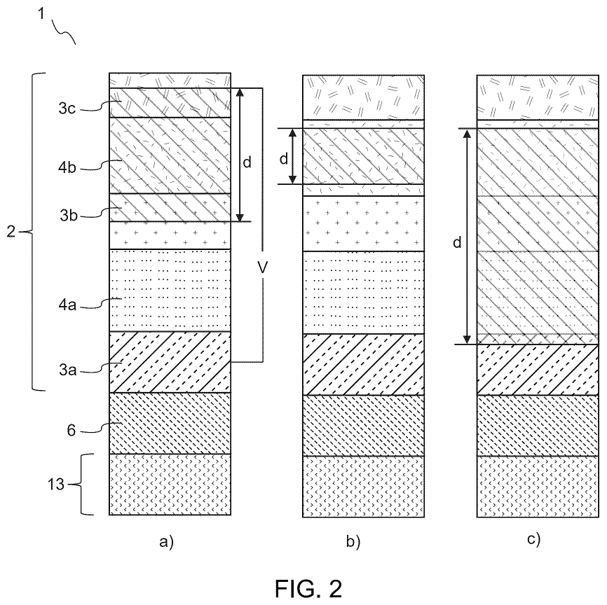

FIG. 2 illustrates the space charge region d of the optoelectronic device 1 of FIG. 1 in dependence on a voltage applied to it. When applying a voltage V of 0V between the first and third layer 3a, 3c, and thus a 0V Bias of the semiconductor layer stack 2, the space charge region d extends from the second region 3b into the third region 3c and comprises the second active region 4b (see a) of FIG. 2). In this state, light with energy E_{g}^{emitter} greater than the bandgap of the second active region 4b (inclusively) can then for example be detected in the second active region 4b. A biasing of the semiconductor layer stack 2 in forward direction causes the space charge region d to close such that holes recombine with electrons only in the second active region 4b emitting light with the energy of the energy E_{g}^{emitter} of the second active region 4b (see b) of FIG. 2). A biasing of the semiconductor layer stack 2 in reverse direction causes the space charge region d to enlarge such that it covers in addition to the second active region 4b the first active region 4a. Light with energy E_{g}^{det} greater than the bandgap of the first active region 4a (inclusively) can then be detected over the whole enlarged space charge region d (see c) of FIG. 2).

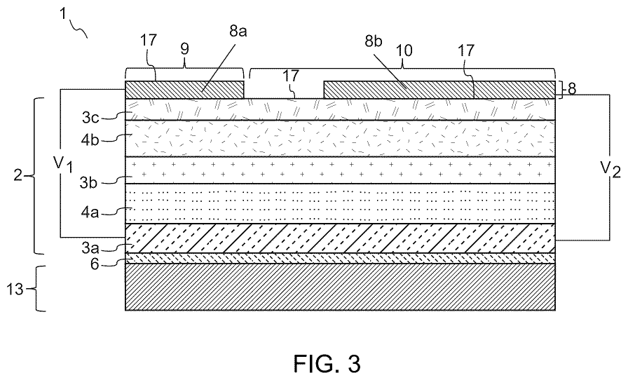

FIG. 3 shows another embodiment of an optoelectronic device 1 in accordance with some embodiments of the proposed principle. In addition to an aforementioned embodiment, the optoelectronic device 1 comprises a top contact element 8 on the third layer 3c to electrically contact the semiconductor layer stack 2 and in particular the third layer 3c. The top contact element 8 comprises a first portion 8a and a second portion 8b arranged spaced from each other on the third layer 3c. The first and second portion 8a, 8b form separate electric contacts for operating an emitter portion 9 of the optoelectronic device and a detector portion 10 of the optoelectronic device 1.

To operate the emitter portion 9 a forward voltage V₁ is applied between the first portion of the top contact element 8a and the bottom contact element 6 and light with an energy Eₕ^{emitter} of the second active region 4b can be emitted via a light emitting area 17 above the emitter portion 9. The light emitting area 17 can in particular be formed by the first portion of the top contact element 8a which therefore is for example of a material substantially transparent for at least the light with the energy E_{g}^{emitter} of the second active region 4b.

To operate the detector portion 10 a reverse voltage V₂ is applied between the second portion of the top contact element 8b and the bottom contact element 6 and light with an energy E_{g}^{det} greater than the bandgap of the first active region 4a (inclusively) and incident on a light incident area 17 above the detector portion 10 can be detected in the enlarged space charge region. The light incident area 17 can in particular be formed by the second portion of the top contact element 8b which therefore is for example of a material substantially transparent for at least the light with energy E_{g}^{det} greater than the bandgap of the first active region 4a (inclusively).

In addition, the bottom contact element 6 can comprise a reflective material layer, covering the first layer 3a. This allows a directional radiation of generated light in the direction of the light emitting area 17 and a more efficient outcoupling of the generated light through the light emitting area 17. On the other hand, the detection efficiency of the optoelectronic device 1 can be increased, as not yet detected but through the semiconductor layer stack 2 propagated light is reflected within the optoelectronic device 1 to be possibly detected “at a further attempt” when propagating back again through the semiconductor layer stack 2.

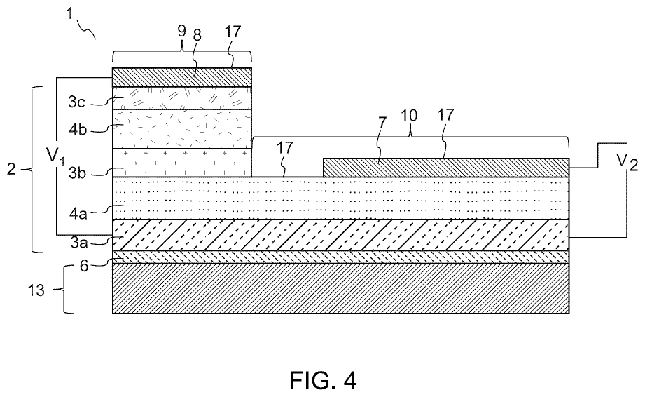

FIG. 4 shows another embodiment of an optoelectronic device 1 in accordance with some embodiments of the proposed principle. In contrast to an aforementioned embodiment, the optoelectronic device 1 comprises a “separate” emitter portion 9 and detector portion 10. This is realized by removing in the detector portion 10 parts of the third layer 3b, the second active region 4b and the second layer 3b. The removal of the second layer 3b is however optional and the second layer 3b can as well remain on the first active region 4a. In the embodiment shown on top of the first active region 4a a middle contact element 7 is arranged, which in this case is in form of a Schottky contact element. In case of the second layer 3b remains on the first active region 4a any other material/element can be used for the middle contact element 7.

As for aforementioned embodiment, the emitter portion 9 and the detector portion can be operated by applying forward and reverse voltage V₁, V₂.

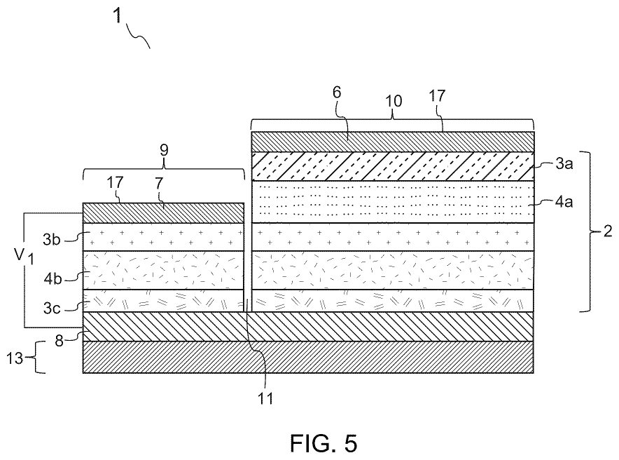

FIG. 5 shows another embodiment of an optoelectronic device 1 in accordance with some embodiments of the proposed principle. In contrast to an aforementioned embodiment, in the detector portion 10 of the optoelectronic device 1 none of the layers of the semiconductor layer stack 2 is removed whereas in the emitter portion 9, the first layer 3a, the first active region 4a and optionally the second layer 3b is removed. In the embodiment shown on top of the second layer 3b a middle contact element 7 is arranged, which in this case comprises a material substantially transparent for at least the light with the energy Eg emitter of the second active region 4b.

Compared to aforementioned embodiments, the semiconductor layer stack 2 is arranged on the carrier substrate 13 upside down with the top contact element 8 facing the carrier substrate 13. In this case the top contact element 8 comprise a reflective material layer, covering the third layer 3c and the bottom contact element 6 on the first layer 3a in the detector portion 10 comprises a material substantially transparent for at least the light with energy E_{g}^{det} greater than the bandgap of the first active region 4a (inclusively). The light emitting area 17 can then in particular be formed by the middle contact element 7 and the light incident area 17 can in particular be formed by the bottom contact element 6.

To further “separate” the emitter portion 9 and the detector portion 10, a gap 11 can be formed between the two portions. However, the structure and material composition of the layers of the emitter and detector portion 9, 10 are the same, as the gap 11 is only created after the layers have been grown on top of each other.

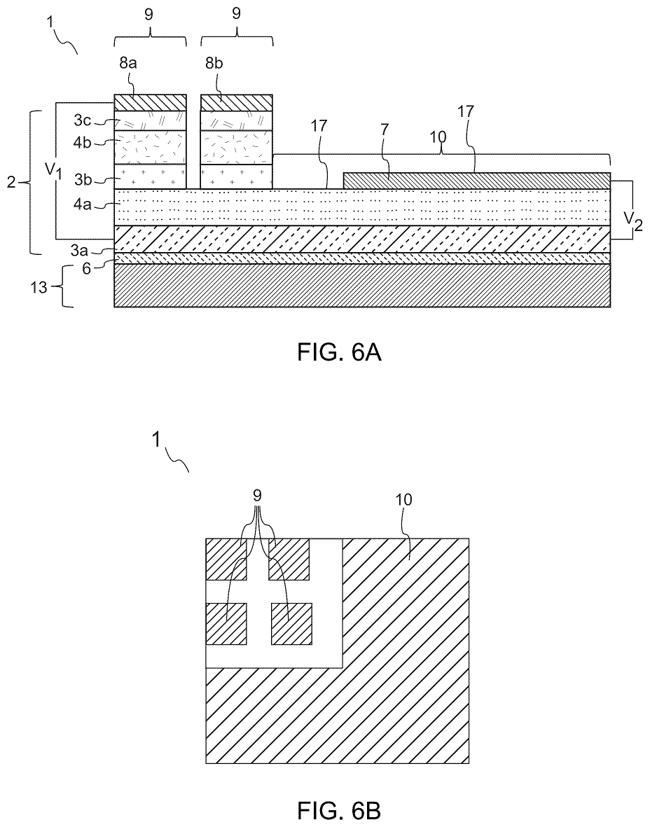

FIG. 6A shows another embodiment of an optoelectronic device 1 in accordance with some embodiments of the proposed principle. In contrast to the embodiment shown in FIG. 4, the optoelectronic device 1 comprises several emitter portion 9 arranged adjacent to each other. As in the embodiment of FIG. 4, parts of the third layer 3b, the second active region 4b and the second layer 3b are removed to form the detector portion 10 on which the middle contact element 7 is arranged. The emitter portion 9 of the embodiment of FIG. 4 is however divided into several portions separated by means of a gap until the first active region 4a each forming a separate emitter portion 9. Each of the emitter portions comprises a portion of the top contact element 8a, 8b to be able to operate the emitter portions 9 separately. By this for example a redundancy between the emitter portions 9 can be achieved.

FIG. 6B shows an exemplary top view of the embodiment of the optoelectronic device 1 of FIG. 6A. The optoelectronic device 1 comprises four emitter portions in one “corner” of the semiconductor layer stack 2 as well as one detector portion 10 extending along the opposing sides of the “corner” of the semiconductor layer stack 2. However, the design and arrangement shown is only to be understood as an example.

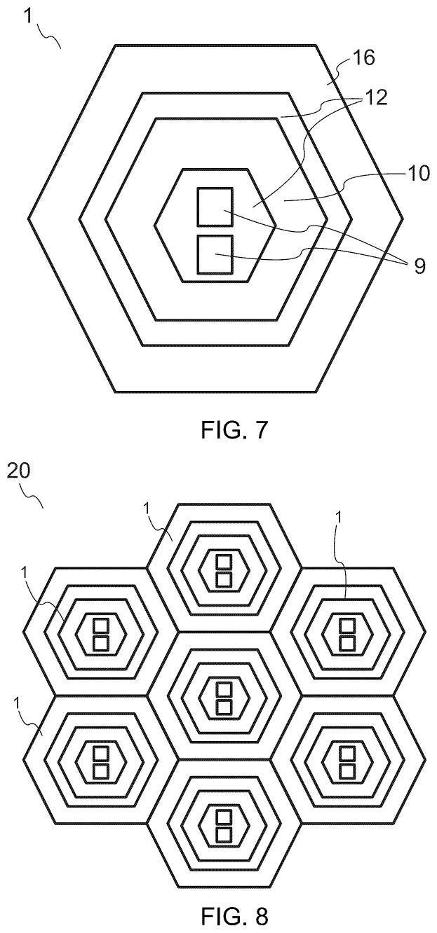

FIG. 7 shows an alternative top view of an embodiment of an optoelectronic device 1 in accordance with some embodiments of the proposed principle. The optoelectronic device 1 comprises two emitter portions arranged in the centre of the semiconductor layer stack 2 as well as one detector portion 10 surrounding the emitter portions. Furthermore, the semiconductor layer stack is enclosed by a filler material 16 extending along the side surfaces of the semiconductor layer stack 2 up to the “highest” layer of the detector portion. Between the filler material 16 and the semiconductor layer stack a reflective coating 12 is arranged on the side surfaces of the semiconductor layer stack 2. By this the detection efficiency of the optoelectronic device 1 can be increased, as not yet detected but through the semiconductor layer stack 2 propagated light is reflected within the semiconductor layer stack 2 to be possibly detected “at a further attempt” when propagating back again through the semiconductor layer stack 2. The reflective coating 12 is also arranged alongside surfaces of the semiconductor layer stack in the emitter portion 9. This allows a directional radiation of light generated in the second active region 4b in the direction of the light emitting area 17 and a more efficient outcoupling of the generated light through the light emitting area 17.

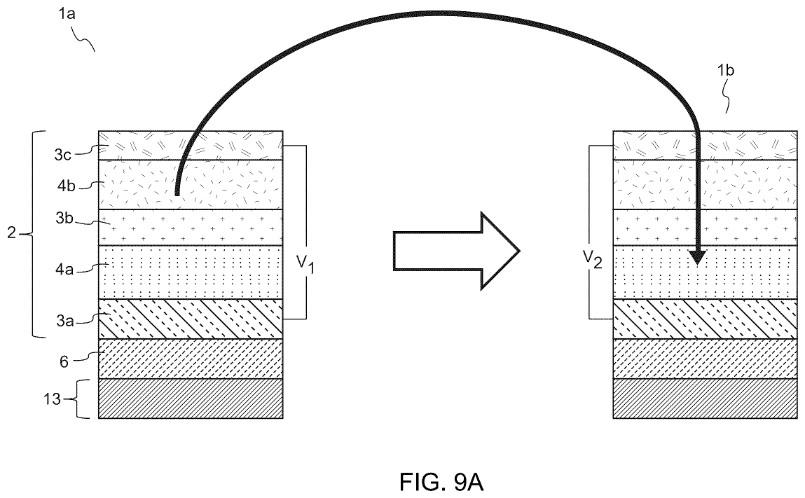

FIG. 8 shows an arrangement 20 in accordance with some embodiments of the proposed principle. The arrangement comprises a plurality of optoelectronic devices 1 as shown in FIG. 7 arranged adjacent to each other on a common carrier substrate (not shown). In the embodiment shown, exemplarily seven optoelectronic devices 1 are arranged on a common carrier substrate. For example, a plurality of optoelectronic devices 1 can be arranged in an array in rows and columns on the common carrier substrate. The common carrier substrate can thereby for example be a CMOS wafer providing the necessary supply circuit for operating the optoelectronic devices 1.

An exemplary method for manufacturing such an arrangement 20 can for example comprise the steps:
Providing the carrier substrate 13;
Providing the bottom contact element 6;
Providing the semiconductor layer stack 2;
Structuring the semiconductor layer stack 2 to receive the emitter portion(s) 9 and the detector portion 10;
Providing a dielectric layer on side surfaces of the semiconductor layer stack 2;
Providing the reflective coating 12 alongside surfaces of the semiconductor layer stack 2;
Providing the filler material 16;
Providing the middle contact element 7 on the detector portion 10; and
Providing the top contact element 8 on the emitter portions 9.

Aforementioned steps are however understood to be exemplary and can vary in their order and/or several steps can be dispensed with/are optional.

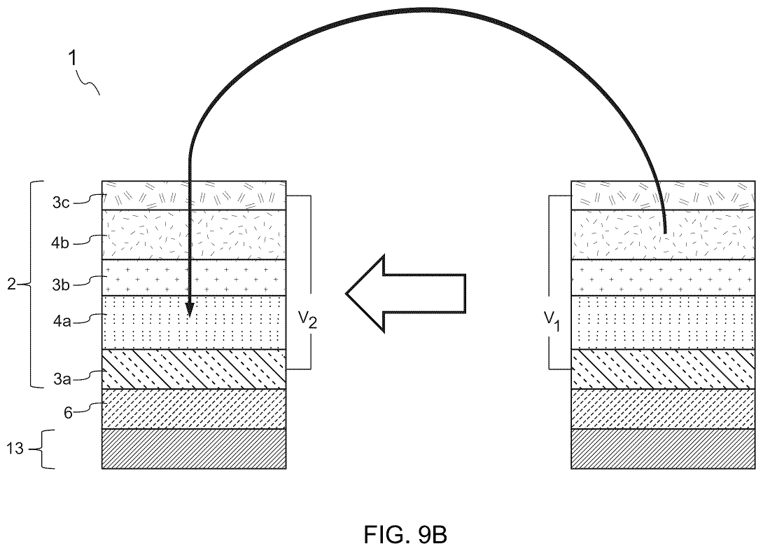

FIGS. 9A and 9B show steps of a method for operating an optoelectronic device in accordance with some embodiments of the proposed principle. FIG. 9A shows the step of sending an optical signal from a first optoelectronic device 1a to a second optoelectronic device 1b, the second optoelectronic device 1b receiving the signal. The first optoelectronic device 1a is therefore applied with a forward voltage V₁ between the first and the third layer 3a, 3c to emit light of a first wavelength. The second optoelectronic device 1b is at the same time applied with a reverse voltage V₂ or voltage equal to 0V between the first and the third layer 3a, 3c to detect the light of the first wavelength. FIG. 9B on the other hand shows the step of sending an optical signal from a second optoelectronic device 1b to the first optoelectronic device 1a, the first optoelectronic device 1a receiving the signal. The second optoelectronic device 1b is therefore applied with a forward voltage V₁ between the first and the third layer 3a, 3c to emit light of a second wavelength. The first optoelectronic device 1a is at the same time applied with a reverse voltage V₂ or voltage equal to 0V between the first and the third layer 3a, 3c to detect the light of the second wavelength. The first and second wavelength can depend on the optoelectronic devices be the same or different.

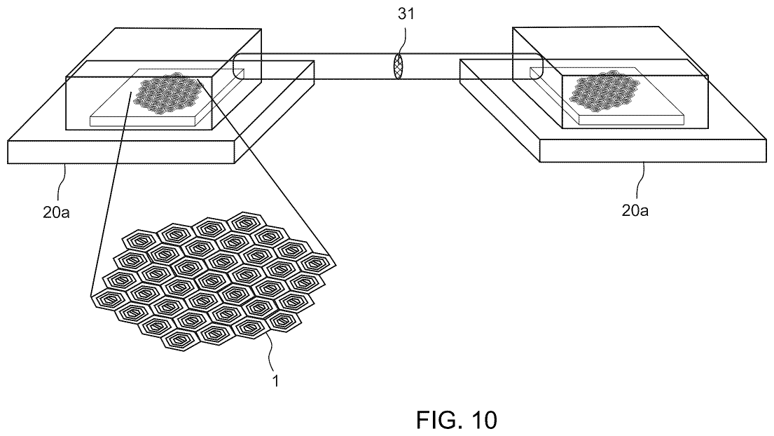

FIG. 10 shows a first embodiment of a system 30 for optical data communication in accordance with some embodiments of the proposed principle. The system 30 comprises a first arrangement 20a of optoelectronic devices 1, a second arrangement 20b of optoelectronic devices 1 and a multicore fibre optically coupling the first and second arrangement. The optoelectronic devices 1 of the first arrangement 20a are optically coupled with a respective optoelectronic device 1 of the second arrangement 20b via an optical fibre 31 of the multicore fibre. As the optoelectronic devices are configured to both emit and detect light of a desired wavelength, only one arrangement of optoelectronic devices is necessary on each side of the communicating objects and a back and forth communication can be provided by the system 30.

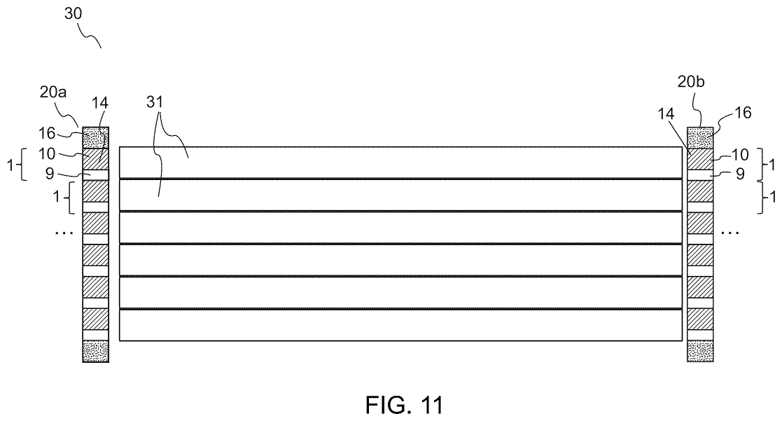

FIG. 11 shows another view of a system 30 of for optical data communication in accordance with some embodiments of the proposed principle. In the system 30, on each of the detector portions 10 of the optoelectronic devices 1, a wavelength filter 14 is arranged being transmissive of at least the light emitted by the emitter portion 9 of the respective optoelectronic device 1 of the opposing arrangement.

1-26. (canceled)

27. An optoelectronic device comprising:
a carrier substrate; and
a semiconductor layer stack arranged on the carrier substrate,
wherein the semiconductor layer stack comprises a first layer, a second layer, a third layer, a first active region between the first and second layers and a second active region between the second and third layers,
wherein the first and second layers comprise a doping of a first conductivity type with the second layer having a higher doping concentration than the first layer,
wherein the third layer comprises a doping of a second conductivity type different from the first conductivity type, and
wherein the first active region comprises a smaller bandgap than the second active region.

28. The optoelectronic device according to claim 27,
wherein the optoelectronic device is configured to emit light in response to applying a voltage in forward direction between the first layer and the third layer, and
wherein the optoelectronic device is configured to detect light in response to applying 0V or a voltage in reverse direction between the first layer and the third layer.

29. The optoelectronic device according to claim 27, further comprising:
a top contact element in electric contact with the third layer; and
a bottom contact element in electric contact with the first layer.

30. The optoelectronic device according to claim 29,
wherein the top contact element or the bottom contact element is substantially transparent for light with energy smaller than or equal to the bandgap of the second active region, and/or
wherein the top contact element comprises a first portion and a second portion arranged on the third layer opposite the second active region distant from each other or wherein the bottom contact element comprises a first portion and a second portion arranged on the first layer opposite the first active region distant from each other, and/or
wherein the top contact element comprises a reflective material layer covering the third layer opposite the second active region or wherein the bottom contact element comprises a reflective material layer covering the first layer opposite the first active region.

31. The optoelectronic device according to claim 27,
wherein the semiconductor layer stack comprises an emitter portion and a detector portion,
wherein the emitter portion comprises at least a portion of the second active region and the third layer, and
wherein the detector portion comprises at least a portion of the first layer and the first active region.

32. The optoelectronic device according to claim 31,
wherein, in the detector portion, the second active region and the third layer and optionally the second layer is removed, or
wherein, in the emitter portion, the first layer and the first active region and optionally the second layer is removed.

33. The optoelectronic device according to claim 31, wherein the emitter portion and the detector portion are spaced from each other by a gap.

34. The optoelectronic device according to claim 31, further comprising a middle contact element in electric contact with the second layer and/or the first active region or the second active region.

35. The optoelectronic device according to claim 34, wherein the middle contact element is a Schottky contact element being in electric contact with the first active region or the second active region.

36. The optoelectronic device according to claim 27,
further comprising an outcoupling structure on a top contact element opposite the carrier substrate or on a bottom contact element opposite the carrier substrate or on the middle contact element opposite carrier substrate, and/or
further comprising an optical element on the top contact element opposite the carrier substrate or on the bottom contact element opposite the carrier substrate or on the middle contact element opposite carrier substrate, in particular a u-lens or a photonic structure.

37. The optoelectronic device according to claim 27, wherein the carrier substrate comprises a supply circuit being in electric contact with a top contact and/or a bottom contact and/or a middle contact element.

38. An arrangement comprising:
a plurality of optoelectronic devices according to claim 27 arranged adjacent to each other on a common carrier substrate.

39. The arrangement according to claim 38,
wherein the optoelectronic devices is arranged in an array in rows and columns, and/or
wherein the optoelectronic devices are optically isolated from each other.

40. A system for optical data communication comprising:
a first arrangement of optoelectronic devices and a second arrangement of optoelectronic devices,
wherein the optoelectronic devices of the first arrangement are optically coupled with a respective optoelectronic device of the second arrangement,
wherein each optoelectronic device of the first and second arrangements comprises an emitter and a detector portion, and
wherein at least one of the first arrangement or the second arrangement is the arrangement according to claim 38.

41. The system according to claim 40,
wherein the optoelectronic devices of the first arrangement are configured to emit light of a first wavelength,
wherein the optoelectronic devices of the second arrangement are configured to detect the light of the first wavelength,
wherein the optoelectronic devices of the second arrangement are configured to emit light of a second wavelength, and
wherein the optoelectronic devices of the first arrangement are configured to detect the light of the second.

42. The system according to claim 41, wherein the first and second wavelength are different from each other.

43. The system according to claim 42, further comprising:
a first wavelength filter arranged above each detector portion of the optoelectronic devices of the first arrangement; and
a second wavelength filter arranged above each detector portion of the optoelectronic devices of the second arrangement,
wherein the first wavelength filter is configured to transmit light of the second wavelength but block light of the first wavelength, and
wherein the second wavelength filter is configured to transmit light of the first wavelength but block light of the second wavelength.

44. A method for operating the system according to claim 41, the method comprising:
emitting the light of the first wavelength by the first optoelectronic device of the first arrangement;
coupling the light of the first wavelength into a first optical fibre;
transmitting the light of the first wavelength to a respective first optoelectronic device of the second arrangement;
coupling the light of the first wavelength into the first optoelectronic device of the second arrangement; and
detecting the light of the first wavelength by the first optoelectronic device of the second arrangement.

45. The method according to claim 44, further comprising:
emitting the light of the second wavelength by the first optoelectronic device of the second arrangement;
coupling the light of the second wavelength into the first optical fibre;
transmitting the light of the second wavelength to the first optoelectronic device of the first arrangement;
coupling the light of the second wavelength into the first optoelectronic device of the first arrangement; and
detecting the light of the second wavelength by the first optoelectronic device of the first arrangement.

46. A method for operating the optoelectronic device according to claim 27, the method comprising:
applying a voltage in a forward direction between the third layer and the first layer or the second layer to emit light of a first wavelength;
outcoupling the light of the first wavelength of the optoelectronic device through a light emitting area arranged on a side of the semiconductor layer stack opposite the carrier substrate; and
applying a voltage equal to 0V or in a reverse direction between the first layer and the third layer or the second layer to detect light of the second wavelength incident on a light incident area of the optoelectronic device arranged on a side of the semiconductor layer stack opposite the carrier substrate.
